(19) United States
(12) Patent Application Publication
(10) Pub. No.: US 2005/0136625 A1
(43) Pub. Date: Jun. 23, 2005

(54) Ultra-thin glass devices

(76) Inventors: Debora Henseler, Erlangen (DE); Karsten Heuser, Erlangen (DE); Georg Wittmann, Herzogenaurach (DE); Ralph Paetzold, Roth (DE)

Correspondence Address: FISH & RICHARDSON P.C., PO BOX 1022, MINNEAPOLIS, MN, 55440-1022, US

(21) Appl. No.: 11/036,757

(22) Filed: Jan. 14, 2005

Related U.S. Application Data
(63) Continuation-in-part of application No. PCT/DE03/02413, filed on Jul. 17, 2003.

(30) Foreign Application Priority Data
Jul. 17, 2002 (DE) 102 32 453.0

(51) Int. Cl. C30B 1/00; H01L 21/20; H01L 21/36; H01L 23/29

(52) U.S. Cl. 438/479; 257/794

(57) ABSTRACT

Techniques for fabricating devices including an ultra-thin glass and such devices are described. An ultra-thin glass substrate having a thickness less than or equal to 200 microns is fixed to a first mechanically stable support such that the substrate can be removed from the support without damaging the substrate. A device is formed on the ultra-thin glass substrate. The first mechanically stable support is removed from the ultra-thin glass substrate.

### CROSS-REFERENCE TO RELATED APPLICATIONS

This application is a continuation application and claims the benefit of priority under 35 U.S.C. Section 120 of International Application Ser. No. PCT/DE2003/02413, filed Jul. 17, 2003, which claims priority to German Application Ser. No. 102 32 453.0 filed Jul. 17, 2002.

### BACKGROUND

The invention relates to a thin or ultra-thin glass, thus a glass of maximum thickness 200 microns.

Ultra-thin glasses are employed in electrical and electronic technology as substrates. In particular, in the manufacture of very light, compact or flexible electronic components or formable displays, e.g., light emitting diode (LED) or organic light emitting diode (OLED) technology, ultra-thin glasses are flexible substrates which are highly resistant to chemicals and thus have preferred uses.

However, such very thin glasses have a major drawback which is common to all glasses: they are brittle and they readily break, especially after they have suffered edge damage.

For stabilization of ultra-thin glasses, which because of their thinness are quite flexible and bendable compared to other glasses, the ultra-thin glasses are treated with a stabilizing coating, such as a polymer layer, adhesively bonded to one side of the glass. However, in many cases this stabilization is insufficient, e.g., when the ultra-thin glasses are used in existing product production lines. The glasses break and cause high rates of process interruption and product wastage; in addition, substantial cleanup and maintenance costs are incurred in the production lines as a consequence of the breakage of the thin glass.

### SUMMARY

Accordingly, an underlying problem of the present invention is to stabilize an ultra-thin glass in a manner such that the glass can be transported and can be used in existing production lines.

A further underlying problem of the invention is to specify applications for the subject glass.

In one aspect, the invention is directed to a method for fabricating a device. An ultra-thin glass substrate having a thickness less than or equal to 200 microns is fixed to a first mechanically stable support such that the substrate can be removed from the support without damaging the substrate. A device is formed on the ultra-thin glass substrate. The first mechanically stable support is removed from the ultra-thin glass substrate.

The ultra-thin glass substrate can be transferred from the first mechanically stable support to a second mechanically stable support. A bonding layer may be fixed to the substrate. The bonding layer can include an adhesive. The bonding layer can include a metallic layer and the ultra-thin glass substrate can be fixed to the support by magnetic forces. The ultra-thin glass substrate can be fixed to the mechanically stable support at a plurality of locations such that portions of the substrate and the support are not fixed together. The mechanically stable support can include metal or glass. OLEDs can be formed on the ultra-thin glass substrate.

In another aspect, the invention can be directed to an apparatus. The apparatus can include an ultra-thin glass substrate having a thickness not greater than 200 microns and a stable support fixed to the ultra-thin glass, wherein the support is fixed to the substrate such that the glass substrate can be removed from the stable support without damaging the glass substrate.

A bonding layer can be between the stable support and the glass substrate. The stable support can be reversibly fixed so as to be dissoluble from the glass substrate. The stable support can be formed of glass. The stable support can have a composition different from the glass substrate and a property similar to the glass substrate, wherein the property is one of a chemical property or a physical property. The property can be one of a thermal coefficient of expansion or chemical reactivity. The ultra-thin glass substrate and the stable support can have equal length and equal width. The stable support can have a greater dimension than the glass substrate, wherein the dimension is one of length or width. The stable support can be releasable from the glass substrate by exposing the stable support to radiation. The stable support can be releasable from the glass substrate by exposing the stable support to solvent.

In another aspect, the invention is directed to method of protecting an ultra-thin substrate with a support. An ultra-thin glass substrate is fixed to a first support to form a first assembly. The first assembly is transported. The ultra-thin glass substrate is removed from the first support. The ultra-thin glass substrate is fixed to a second support to form a second assembly. The ultra-thin glass substrate is processed to form one or more layers on the substrate.

The principal subject matter of the invention is an ultra-thin glass with a thickness not greater than 200 microns which is releasably fixed to a stable support.

Implementations of the invention can include none, one or more of the following advantages. The handling and processing of thin and ultra-thin glass can be enabled with the aid of releasable bonding or fastening to a stable support. Existing processing for ordinary glass can be utilized in processing the substrate/support assembly. Thin glass is substrate material which can enable creation of thin, light, and flexible applications. The introduction of thin glass into the market on a broad scale has been impeded at least in part by the inherent fragility of the material, which can be detrimental to shipping, cleaning, and processing.

By attaching a thin or ultra-thin substrate to a support, existing manufacturing techniques can be used to process the substrate without modification, i.e., existing technology used to manufacture OLEDs with a non-flexible (thus not ultra-thin) glass substrate can be used to process thin or ultra-thin substrates. The proposed system with a stable support can be used from the time of production of the glass up to and including the end product, or may be used where appropriate at particular process steps.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIG. 1A shows a schematic of an ultra-thin glass substrate fixed to a mechanically stable support.

FIG. 1B shows a schematic of active elements of a device processed on the ultra-thin glass substrate.

FIG. 1C shows a schematic of a device comprising active elements on a substrate.

FIG. 2 shows a schematic of a device fixed to the mechanically stable support by means of a bonding layer.

FIG. 3 shows a schematic of a device fixed at various points to the mechanically stable support.

FIG. 4 shows a schematic of a device fixed to a mechanically stable support which extends beyond the edges of the substrate.

FIG. 5 schematically shows an OLED-device encapsulated by a cap.

Like reference symbols in the various drawings indicate like elements.

### DETAILED DESCRIPTION

A substrate of a thin or ultra-thin glass, such as a substrate of less than about 200 microns, can be used in forming a device. Prior to formation, the substrate typically is transported from a manufacturing or storage site to a processing location. The glass substrate, or glass plate, is then processed in one or more ways to form the device. Transporting and processing the substrate can expose the substrate to risk of damage. To reduce the risk of damage during transport and processing, the substrate can be fixed to a stable support.

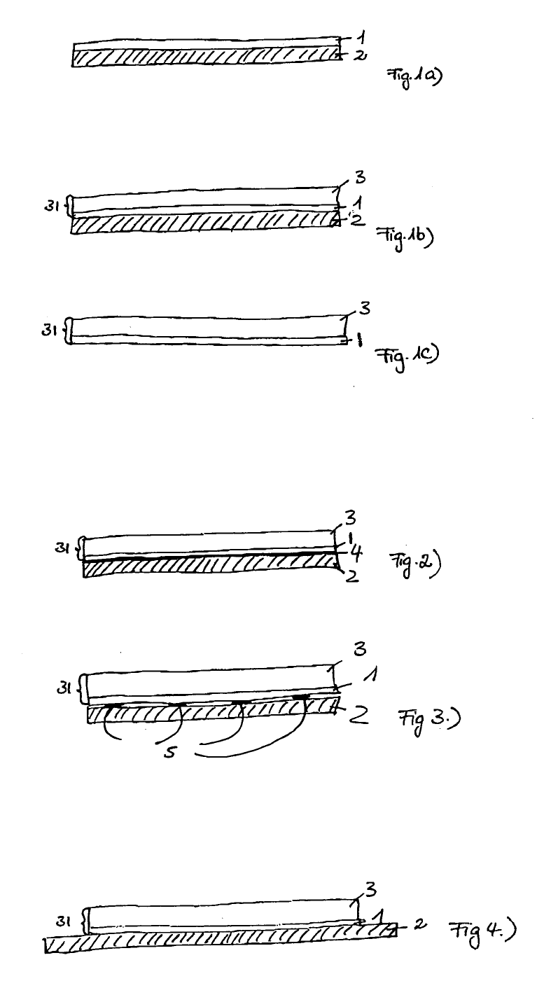

Referring to FIG. 1A, an ultra-thin glass substrate 1 is fixed to a mechanically stable support 2 or carrier. In one implementation, the stable support 2 is a standard thick glass, so that the support has identical or similar chemical and/or physical properties to those of the ultra-thin glass. This implementation is suitable for utilization of the ultra-thin glass in existing fabrication techniques or production lines, where the ultra-thin glass is used as a substrate for electronic components under circumstances where the ultra-thin glass is exposed to various environments, e.g., temperature, solvents, vapors, etc. In other implementations, the materials suitable for use as stable supports are not limited and can include metallic, natural, synthetic, organic or inorganic materials.

Referring to FIG. 1B, active elements 3 of a device 31 are processed on the ultra-thin glass substrate 1, which is fixed to the mechanically stable support 2. The support can be changed as required at each step of transporting and processing, or when the ultra-thin glass undergoes a plurality of fabrication steps at different locations. A stable support employed for shipping can alternate with one or more stable supports which are used in various production lines. A first support, such as a metal support, can be a stable support employed to protect the ultra-thin glass during shipping. A second support having different chemical and/or physical properties can be used during a first production step, such as the production of an indium tin oxide (ITO) layer on the substrate. A third support can be used during a second processing step, such as a step of coating the substrate with a hole-transport material.

The requirements which these stable supports must satisfy can be different for different situations. A stable support comprised of a glasslike material (having a glass, porcelain enamel, or similar surface), can be more suitable for processing steps than a metal support. A stable support employed for shipping can extend beyond the edges of the ultra-thin glass, as shown below in FIG. 4. Another stable support which supports the ultra-thin glass during a production process can have dimensions which accurately match those of the ultra-thin glass, so that the substrate/support assembly will fit existing forms and structures used in the processing.

Referring to FIG. 1C, the support is removed when processing is complete. The device 31 having active elements 3 is supported only by the support 2. Removing the support allows the substrate to flex.

In one implementation, the stable support can be bonded to the ultra-thin glass substrate, such as with a bonding or fastening layer. The fixing and/or separation of the stable support can be accomplished by UV radiation, solvent application, microwave radiation, or other means. The bond can be releasable or reversible. The requirements applied to the bonding layer can vary depending on the application. The bonding layer can facilitate the fixing of the ultra-thin glass, or can accomplish adhesive bonding where the ultra-thin glass is at least temporarily bonded to a support, such as a thicker glass or plastic.

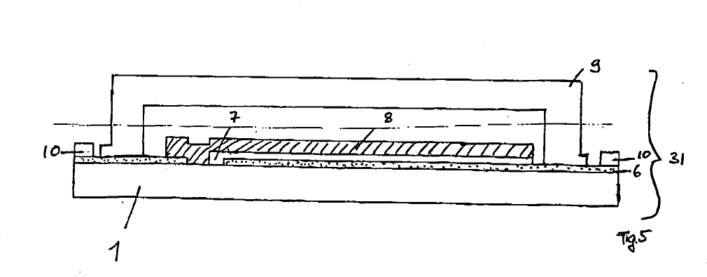

Referring to FIG. 2, a device 31 having active elements 3 on a substrate 1 is fixed to the mechanically stable support by a bonding layer, such as an adhesive and/or coating. In one implementation, the ultra-thin glass substrate is coated with a metal layer by vapor deposition and the substrate is attached to a magnetic support. In another implementation, the ultra-thin glass is coated with an adhesive coating, such as a coating that is subsequently removable. The adhesive coating is used to fix the glass to the stable support.

Referring to FIG. 3, a device 31 comprising active elements 3 on a substrate 1 is fixed at various points to a mechanically stable support 2. In one implementation, suction cups bond portions of the support 2 to the substrate 1. These miniaturized suction cups can be releasably fixed to the support only at certain locations, e.g., spot locations. In another implementation, a bonding material formed only at points on the support and does not cover the entire surface of the support.

Referring to FIG. 4, a device 31 having active elements 3 on a substrate 1 is fixed to a mechanically stable support 2, where the support 2 extends beyond the edges of the device 31. The edge of the support 2 that extends beyond the device can be used to handle the assembly without damaging the substrate 1 or active elements 3.

In one implementation, the substrate and the support are produced as one product. An assembly of two glasses (thin glass and support) bonded together during production at particular locations (e.g., spot locations) can be formed when the substrate and/or support are in a fluid state or when the substrate and/or support are not in an amorphous solid state. The support and the substrate can be bonded together, such as with a fluid gas or gas welding.

In one implementation, the ultra-thin glass is fixed to a stable support immediately after the glass is produced. The glass can remain fixed to the stable support while the glass undergoes processing as a substrate for an electronic device and is transported to the various processing locations. As described above, it is not necessary that the support remain the same support throughout processing; there can be a sequence of supports. The separation of the stable support can occur at any stage or location of the processing of the ultra-thin glass. According to one implementation, the ultra-thin glass substrate is not removed from the (last) stable support until after the final encapsulation of the electronic device, immediately before said device is installed into an electronic component. The electronic device can include a finished encapsulated OLED on a substrate comprised of ultra-thin glass, which is installed in an electronic component, e.g., a photodetector. Other examples of flexible electronic components which are fabricated on ultra-thin glass or between ultra-thin glasses are solar cells, organic light-emitting diodes (OLEDs), displays, or similar applications in which one side of the electronic component is transparent.

Referring to FIG. 5, a complete OLED device can be formed and the support can be removed when the assembly is complete. Layers are formed on the substrate 1 to form the active portion of the device 31. The layers can include a first electrode 6, active organic material 7 and a second electrode 8, forming an OLED. A cap 9 can be secured to the substrate 1, thereby sealing the active portion of the device 31 from the environment. Outside the cap 9, bond pads 10 can be provided for the electrical connection to the active portion of the device 31. The support 2 is removed from the glass substrate 1. As soon as the ultra-thin glass is released from the support, the glass regains its flexibility and/or original properties.

In one implementation, the stable support can not be completely separated from the ultra-thin glass. One or more regions of the ultra-thin glass can be separated from the support, such as by glass cutting.

The chemical and physical characteristics of the stable support can differ substantially from the substrate. The stable support can be required to have the same thermal coefficient of expansion and the same chemical reactivity as the glass substrate, but also be able to be released, dissolved or otherwise removed from the ultra-thin glass substrate, at least at certain locations. When the separation of the stable support from the substrate occurs, the substrate, possibly with a coating or laminated structure formed thereon, remains intact. Means which are candidates for releasing the support from the substrate (or fixing the support to the substrate) include radiation (UV, IR, microwaves, etc.), coatings, adhesive bonding, magnetic fixing, solvents (gaseous, liquid, or solid), gels, gauzes, meshes, grids, or mechanical means. In one implementation, the means or media has a destructive effect on the stable support.

The described invention discloses a concept of handling and processing thin and ultra-thin glass (glass with a thickness not substantially greater than 200 microns) with the aid of releasable bonding or fastening to a stable support. Existing processing for ordinary glass can be utilized in processing the substrate/support assembly. Thin glass is substrate material which can enable creation of thin, light, and flexible applications. The introduction of thin glass into the market on a broad scale has been impeded at least in part by the inherent fragility of the material, which can be detrimental to shipping, cleaning, and processing.

By attaching a thin or ultra-thin substrate to a support, existing manufacturing techniques can be used to process the substrate without modification, i.e., existing technology used to manufacture OLEDs with a non-flexible (thus not ultra-thin) glass substrate can be used to process thin or ultra-thin substrates. The proposed system with a stable support can be used from the time of production of the glass up to and including the end product, or may be used where appropriate at particular process steps, with some variation.

A number of embodiments of the invention have been described. Nevertheless, it will be understood that various modifications may be made without departing from the spirit and scope of the invention. Accordingly, other embodiments are within the scope of the following claims.

1. A method for fabricating a device, comprising:
fixing an ultra-thin glass substrate having a thickness less than or equal to 200 microns to a first mechanically stable support such that the substrate can be removed from the support without damaging the substrate;
forming a device on the ultra-thin glass substrate; and
removing the first mechanically stable support from the ultra-thin glass substrate.

2. The method according to claim 1, further comprising transferring the ultra-thin glass substrate from the first mechanically stable support to a second mechanically stable support.

3. The method of claim 1, wherein fixing the first mechanically stable support to the ultra-thin glass substrate including fixing a bonding layer to the substrate.

4. The method of claim 3, wherein the bonding layer includes an adhesive.

5. The method of claim 3, wherein:
the bonding layer includes a metallic layer; and
the ultra-thin glass substrate is fixed to the support by magnetic forces.

6. The method of claim 1, wherein fixing the ultra-thin glass substrate to the first mechanically stable support includes fixing the ultra-thin glass substrate at a plurality of locations such that portions of the substrate and the support are not fixed together.

7. The method of claim 1, wherein the mechanically stable support includes metal or glass.

8. The method of claim 1, wherein the forming a device on the ultra-thin glass substrate includes forming an OLED-device on the ultra-thin glass substrate.

9. An apparatus, comprising:
an ultra-thin glass substrate having a thickness not greater than 200 microns; and
a stable support fixed to the ultra-thin glass, wherein the support is fixed to the substrate such that the glass substrate can be removed from the stable support without damaging the glass substrate.

10. The apparatus of claim 9, further comprising:
a bonding layer between the stable support and the glass substrate.

11. The apparatus of claim 9, wherein the stable support is reversibly fixed so as to be dissoluble from the glass substrate.

12. The apparatus of claim 9, wherein the stable support is formed of glass.

13. The apparatus of claim 9, wherein the stable support has a composition different from the glass substrate and a property similar to the glass substrate, wherein the property is one of a chemical property or a physical property.

14. The apparatus of claim 13, wherein the property is one of a thermal coefficient of expansion or chemical reactivity.

15. The apparatus of claim 9, wherein the ultra-thin glass substrate and the stable support have equal length and equal width.

16. The apparatus of claim 9, wherein the stable support has a greater dimension than the glass substrate, wherein the dimension is one of length or width.

17. The apparatus of claim 9, wherein the stable support is releasable from the glass substrate by exposing the stable support to radiation.

18. The apparatus of claim 9, wherein the stable support is releasable from the glass substrate by exposing the stable support to solvent.

19. A method of protecting an ultra-thin substrate with a support, comprising:
fixing an ultra-thin glass substrate to a first support to form a first assembly;
transporting the first assembly;
removing the ultra-thin glass substrate from the first support;
fixing the ultra-thin glass substrate to a second support to form a second assembly; and
processing the ultra-thin glass substrate to form one or more layers on the substrate.
